(19) United States
(12) Patent Application Publication
(10) Pub. No.: US 2009/0146134 A1
(43) Pub. Date: Jun. 11, 2009

(54) Semiconductive percolating networks

(76) Inventors: Xiang-Zheng Bo, Austin, TX (US); Graciela B. Blanchet, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/661,155

(22) PCT Filed: Aug. 25, 2005
(86) PCT No.: PCT/US05/30632

§ 371 Date: Mar. 5, 2008

Related U.S. Application Data
(60) Provisional application No. 60/605,343, filed on Aug. 27, 2004.

(51) Int. Cl. H01L 51/30

(52) U.S. Cl. 257/40; 438/99; 257/E51.024

(57) ABSTRACT

The present invention relates to a semi-conductive composition comprising carbon nanotubes in a matrix. These semiconductive compositions are useful in printing semiconducting portions of thin film transistors.

### FIELD OF THE INVENTION

The present invention relates to a composition comprising carbon nanotubes in a semiconductive matrix. These compositions are useful in printing semiconducting portions of thin film transistors.

### TECHNICAL BACKGROUND

Blanchet et al. in U.S. patent application Ser. No. 10/374,875 describes formulations of carbon nanotubes in a conducting polyaniline matrix.

It was found that there is a need for a formulation of carbon nanotubes in a polymer or oligomer resulting in a semiconducting matrix.

### SUMMARY OF THE INVENTION

The present invention is a composition comprising a host matrix and 0.01 to 10% of volume of carbon nanotubes, preferably 0.01 to 1% which have been separated from the large ropes of nanotubes which are formed during their production. The large ropes are separated by being dispersed into an aqueous solution and then redispersed in an organic solvent. The nanotubes are subsequently linked by semiconducting materials.

The present invention is also a composition comprising a semiconducting host and 0.01 to 10% of volume of carbon nanotubes, preferably 0.01 to 1% that have been separated from the large ropes of nanotubes which are formed during their production into an aqueous solution. The nanotubes are subsequently dispersed in a semiconducting matrix.

A further embodiment of the present invention is a process comprising coating the above-cited composition on a donor element, contacting the donor element with a receiver element such that the coating lies between the donor element and the receiver element, and irradiating the coating through the donor element with a laser to transfer the coating on the donor element to the receiver element.

A yet further embodiment of the present invention is a process comprising inking the protruded regions of a stamp or flexographic plate with a solution of the above-cited composition, contacting the stamp or plate onto a receiver element such that the inking solution is transferred onto the receiver element with the pattern of the stamp protrusions.

Another embodiment of the present invention is a process comprising delivering a solution of the above-cited compositions onto a receiver element via an ink jet nozzle.

A further embodiment of the present invention is a transistor with a semiconductor comprising the above-cited compositions.

### BRIEF DESCRIPTION OF THE DRAWINGS

FIG. 1A illustrates a cross section of the test transistor configuration. FIG. 1B illustrates the I,V curve of Example 1.

FIG. 2A illustrates the gate sweep of the transistor of Example 2. FIG. 2B shows the I,V curve of the transistor of Example 2.

FIG. 3 shows the I,V curve of the transistor of Example 3.

FIGS. 4 A, B, C, D show an atomic force micrographs (AFM) of Example 3 with 0.05, 0.1, 0.25 and 1% carbon nanotube content.

FIG. 5 shows the mobility and transconductance of polythiophene/CNT composites as a function of CNT concentration.

FIG. 6 shows the on/off ratio and off current of the transistors of FIG. 5.

FIGS. 7 a, b, c, d show AFM images of SWNT's spun from two different solution concentrations at (a) 5 mg/L and (c) 20 mg/L and (b) and (d) are AFM images of the corresponding bi-layers with 200-Å-thick pentacene evaporated at 0.2 Å/s on top of SWNT's. The letters S and D indicate the Au source and drain electrodes.

FIG. 8 shows the X-ray diffraction spectra of 200 A pentacene films evaporated at 0.2 Å/s onto bare SiO₂ and onto a SWNT array spun onto SiO₂ dispersion.

FIG. 9 shows the effective linear and saturation mobilities of TFT pentacene bi-layers as a function of the SWNT concentrations.

FIG. 10 shows the channel length of non-percolating arrays of SWNT as a function of increasing SWNT content and on/off ratio of bottom gate devices (at V_{ds}=−50 V) for various SWNT concentrations are shown in diamonds and circles, respectively

FIGS. 11 A, B, and C show an AFM of a semiconductor evaporated onto SiO₂ and evaporated onto a 0.8 mg/L and 50 mg/L carbon nanotube array. The films are 400 Å in thickness.

FIG. 12 shows the effective mobility and transconductance of semiconducting bi-layer as a function of carbon nanotube content.

FIG. 13 shows the off current and on/off ratio as a function of nanotube content.

FIGS. 14 A and B show the gate sweep curves of a polyaniline (PANI) composite film with 1% and 2% by weight of single wall carbon nanotubes.

FIGS. 15 A and B show the gate sweep curves of a polyaniline (PANI) film with 5 and 10% by weight of single wall carbon nanotubes.

FIG. 16 A shows gate sweep curves of water-soluble CNT in a PANI host at 0.5% CNT by weight. FIG. 16 B shows the I,V curve of Example 13.

FIG. 17 A shows the gate sweep and FIG. 17 B shows the I,V curves of water-soluble CNT at 1% by weight in an insulating host.

### DETAILED DESCRIPTION OF THE INVENTION

This invention discloses a composition comprising carbon nanotubes dispersed in a semiconducting or insulating matrix. It demonstrates an alternative path for achieving high transconductance organic transistors in spite of relatively large source to drain distances. The improvement of the electronic characteristic of such a scheme is equivalent to a 60-fold increase in mobility of the underlying organic semiconductor. The method is based on networks, which are created from a dispersion of individual single wall carbon nanotubes (SWNT) and narrow ropes within an organic semiconducting host.

The carbon nanotubes described herein have been separated from the ropes of nanotubes, which form during their production process. They are dispersed at a concentration of 0.01 to 10%, preferably 0.01 % to 1%, in a matrix. This leads to the formation of networks of carbon nanotubes, which may be connected via semiconducting polymers, semiconducting oligomers, or barely conducting polymers coated on the nanotubes. At nanotube concentrations below the formation of a percolation network, the majority of current paths between source and drain follow the metallic nanotubes, but require a short, switchable semiconducting link to complete the circuit. Such electrically semiconductive organic composite can be patterned such that the film retains adequate electron mobility.

The carbon nanotubes can be dispersed into small amounts of semiconducting material prior to their dispersion into an insulating matrix. This leads to the formation of semiconducting carbon nanotube networks in an organic matrix for applications in which the resulting semiconducting layer functions as the transport layer in an organic electronic device. With these nanotube/semiconducting composites, a 60×reduction is effectively achieved in source to drain distance, which is equivalent to 60-fold increase of the mobility of the starting semiconducting material with a minor decrease of the on/off current ratio. These field-induced networks allow for the fabrication of high-transconductance transistors having a relatively large source to drain distances that can be manufactured by commercially available printing techniques.

It has been found that approximately two thirds of individual carbon nanotubes are semiconducting and the remaining one third is conducting. Although, the semiconducting to metallic ratio is also dependent on the nanotube synthesis method and specific catalyst used in their preparation. When the nanotubes are separated or dispersed from the large ropes in which they agglomerate during their production, networks of small ropes and individual tubes are obtained and can be dispersed in a matrix. At nanotube concentrations in the range of 0.01 to 10 percent by volume, the connectivity of the carbon nanotube varies considerably. While the onset of a measurable off current points to the formation of a few conducting pathways between source and drain at concentrations as low as 0.0025%, many others, remain interrupted by stretches of semiconducting material. However, interrupted links that fall close to the interface to the dielectric are switchable and can be turned on and off via the gate, which creates a thin electron channel within the semiconductor. It is this switchable network that becomes the active component between source and drain rather than it being any homogeneous material. Carriers move largely within the highly conducting metallic nanotubes from source to drain. Only occasionally and for distances short compared to the s-d length do they travel through the activated semiconducting channel. This represents an effective shortening of the s-d distance, giving raise to an equivalent increase in the transconductance. This notion represents the central part of our invention. A nearly percolating network of nanotubes is a network where complete 3 dimensional pathway of contact between the desired points (such as a source and a drain electrode) is almost, but not completely established. Gaps remain in the conductive pathway of touching nanotubes. The existence of these gaps is manifested in an on/off ratio of a composite transistor of 10,000 or greater. While the onset of a measurable I_{off}, points to the formation of a few conducting pathways between source and drain, many others, remain interrupted by stretches of semiconductor. However, interrupted links that fall close to the interface to the dielectric are switchable and can be turned on and off via the gate, which creates a thin electron channel within the semiconductor. It is this switchable network that becomes the active component between source and drain rather than it being any homogeneous material. Carriers move largely within the highly conducting metallic nanotubes from source to drain. Only occasionally and for distances short compared to the s-d length do they travel through the activated PHT channel. This represents an effective shortening of the s-d distance, giving raise to an equivalent increase in the transconductance.

As the CNT concentration increases, the number of switchable current paths increases and the transconductance, gₘ, rises. Since mobility enters the transconductance linearly, μₐₚₚ tracks gₘ. However, according to our model it would be more appropriate to think of the enhancement in gₘ as an effective reduction of the channel length, |_{eff} ∝1/μₐₚₚ, while the mobility of the semiconducting links remains constant.

As the nanotube concentration increases, the on/off ratio of these semiconducting composites when used as the transport layer of thin film transistors decreases due to the increased content of conducting tubes. At considerable higher concentrations, a 3-dimensional percolating network of conducting nanotubes are formed and the composite of nanotubes in the matrix is also conducting. Thus, composites containing semiconducting and metallic carbon nanotubes can be formed to be semiconductors for use in thin film transistors. The presence of the metallic tubes shortens the channel length increasing the effective mobility.

If the host matrix in which the network is embedded is a polymer, the composite may also be deposited as the active semiconducting layer in a transistor by various printing processes. The semiconducting layer can be printed via a thermal transfer process, printed using a photo-imageable printing plate (e.g., offset and flexo), an elastomeric molded plate such as a micro-contact printing plate or ink jetted. Improved electron mobility may also be achieved through the addition of semiconductive media such as semiconducting nanorods with high aspect ratios and semiconducting like mobilities. Since the nanotube concentration is considerably lower than that required of fillers, the processability of the host polymer is maintained while the mobility is increased.

Organic semiconductors such as pentacene and polythiophene, who have a π-electron system in their backbone consist of a sequence of aromatic rings. In particular, the mobility of these materials is quite low relative to their inorganic counterparts. Over the last 10 years, there has been considerable interest in developing organic semiconductors with high mobility that could be used in active electronic devices.

Tailoring the transport properties of organics has been achieved utilizing three different strategies:
1) Modifying the intrinsic bulk properties by altering the chemical composition and structure of the starting material.
2) Altering the properties of the polymer or oligomer at the molecular level tailoring charge transport and molecular arrangement.
3) Tailoring the electrical properties by a geometrical modification rather than a chemical modification. Incorporating microscopic pieces such as carbon nanotubes or inorganic nanorods into the host polymer to form a semiconducting network in the host polymer.
   Although, the chemical routes clearly provide efficient pathways to increase mobility in organic materials, it seems to be limited and materials exhibit lack of stability under ambient conditions. Organic thin film transistors (TFTs) have been of great interest due to their low cost, mechanical flexibility, and large area coverage in applications of flat panel displays, radio frequency identification tags, and integration with organic optoelectronics as reported in H. Sirringhaus, et al., Science, 280: 1741 (1998)., P. F. Baude, et al., Appl. Phys. Lett., 82: 3964 (2003) and G. B. Blanchet, et al. Appl. Phys. Lett., 20: 463 (2003)

Solution-processable polymers can be potentially used in a reel-to-reel production process of thin film transistors, thus reducing manufacture cost further compared with vacuum deposited organic films. In principle, organic materials have greater flexibility and easier tunability relative to the silicon-based counterparts. However, solution-based organic materials have low field-effect mobilities (10⁻³-10⁻⁶ cm²/Vs). Thus, considerable activity has been focused on the development of semiconductor materials with high mobilities for applications in TFT's due to vast variety of organic materials available. Similarly, semiconducting oligomers, which could be deposited via thermal evaporation, also show moderate mobilities relative to inorganic counterparts. Poly(alkylthiophenes), oligothiophenes, pentacene, phthalocyanines are just a few examples of such semiconductors. In addition, commercialization of organic electronic devices requires the ability to pattern the semiconducting layer. Imaging processes such as laser thermal transfer, ink jet or micro-contact printing have been described for such applications and are appropriate methods to deposit patterns of the compositions of the present invention in the production of TFTs. Throughout imaging processes, the resolution of the images as well as device performance is controlled. In particular, the mobility of the organic semiconducting film must be preserved throughout the imaging process. The mobility of organic semiconducting oligomers requires a considerable degree of crystalline order with large grain size and limited number of grain boundaries. Semiconducting polymers require instead a high degree of regio-regularity to achieve high mobility. In both these systems imaging via a laser process disrupts crystallinity, order and thus mobility. This invention presents paths towards increasing mobility by designing single wall carbon nanotube (SWCNT) composite materials. TFTs using the composite as transport channel have been fabricated. In contrast, the semiconducting networks of this invention can be imaged via a laser transfer technique, micro-contact, photo-imageable plates and ink jet. In addition, since the bulk of the material is not actively contributing to the overall film mobility, it can be selected for its processability, nanotube affinity and compatibility with a specific printing method. Using the present invention, one can assemble organic semiconductors with potentially much higher mobility than today's choice (pentacene) and considerably higher processability. Unlike pentacene, these networks can be potentially imaged with high resolution using thermal transfer methods, micro-contact printing and ink jet. The materials disclosed here are appropriate for applications as transport layer in plastic TFT transistors in microelectronics.

The compositions of the present invention require that the nanotubes be dispersed from the agglomerate ropes, which are formed during the production of the nanotubes into narrow ropes and individual tubes. As outlined in the examples, this can be done by dispersing the nanotubes into an aqueous solution and then re-dispersing them in an organic solvent.

Additionally, the carbon nanotubes may be coated prior to dispersion in the host matrix to increase the electron mobility above that of composites where the nanotube merely touch. The coating may be a semiconductor or insulator or a barely conductive polymer. By “barely conductive,” it is meant that the electrical conductivity is less than 10⁻⁶ S/cm.

By carbon nanotubes herein is meant carbon atoms bonded together in a hexagonal pattern to form long cylinders. Nanotubes can also be formed of multiple layers of walls. Carbon nanotubes were discovered about 1991. The nanotubes used herein were obtained from Rice University, Houston, Tex., U.S.A.

Preferred solvents herein are selected from the group consisting of ortho di-chloro benzene, water, xylenes, toluene, cyclohexane, chloroform, or mixture thereof with polar solvent such as isopropanol, 2-butoxyethanol, where the content of the polar solvent is preferably less than 25% by weight, toluene, cyclohexane, chloroform, isopropanol, 2-butoxyethanol and mixtures thereof.

### EXAMPLES 1-3

These examples illustrate the effect of single wall carbon nanotubes (SWNT) dispersed in polythiophene. Single wall nanotubes obtained from Rice University, Houston, Tex., were dispersed in ortho di-chloro benzene to a concentration of 0.01 mg/ml. SWNT resulting from this dispersion are a few nanometer in diameter or single tubes.

To prepare the polythiophene matrix, 1 gram of Aldrich polythiophene (PTH) was purified in house following standard purification procedures. A 0.5% by weight solution of PTH in anhydride chloroform was prepared in a dry box. The solution was stirred with a stir bar at room temperature for about 48 hours until no solids remained. The thin film of the control sample was prepared by spin coating a thin film at 2000 RPM for 30 seconds onto a clean Si/SiO₂ wafer with Au pattern sets of source and drains. The spun semiconducting layer was then baked at 80° C. for 30 minutes. This provided the transport layer of a thin film transistor in a bottom gate configuration (Example 1). The doped Si wafer was used as the gate electrode. A 250 nm thermally grown SiO₂ film on the Si wafer was used as the dielectric onto which 40 sets of source and drains of various widths (W) and channel lengths (L) were patterned by photolithography. The patterned wafers were cleaned following the following procedure: 1) acetone rinse 3 times, 2) methanol rinse 3 times, 3) de-ionized water rinse, 4) blow dry and 5) O₂ plasma for 5 minutes.

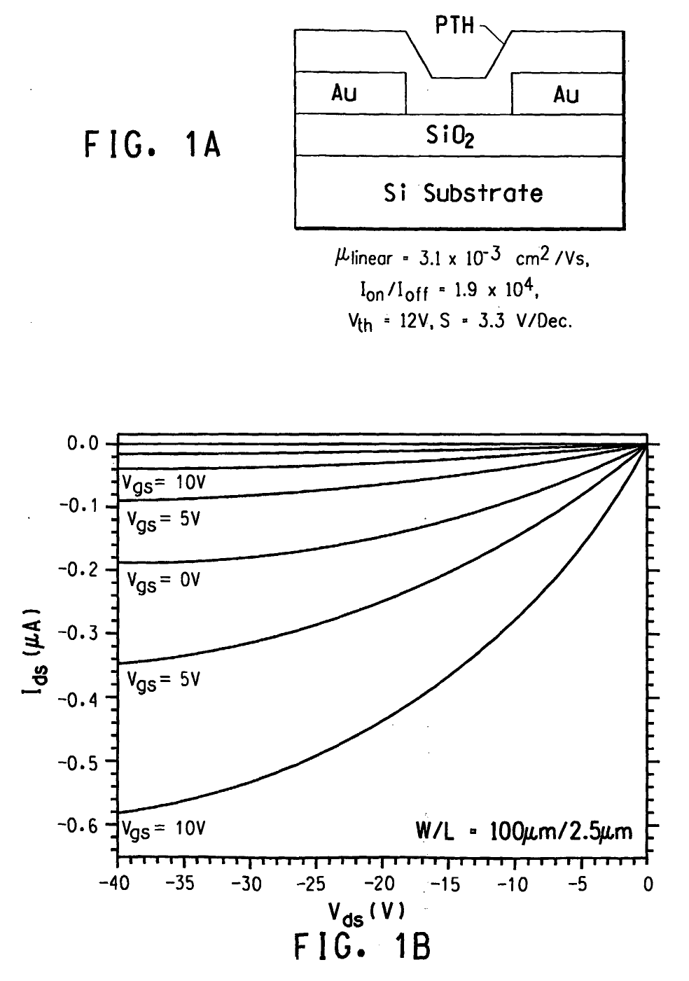

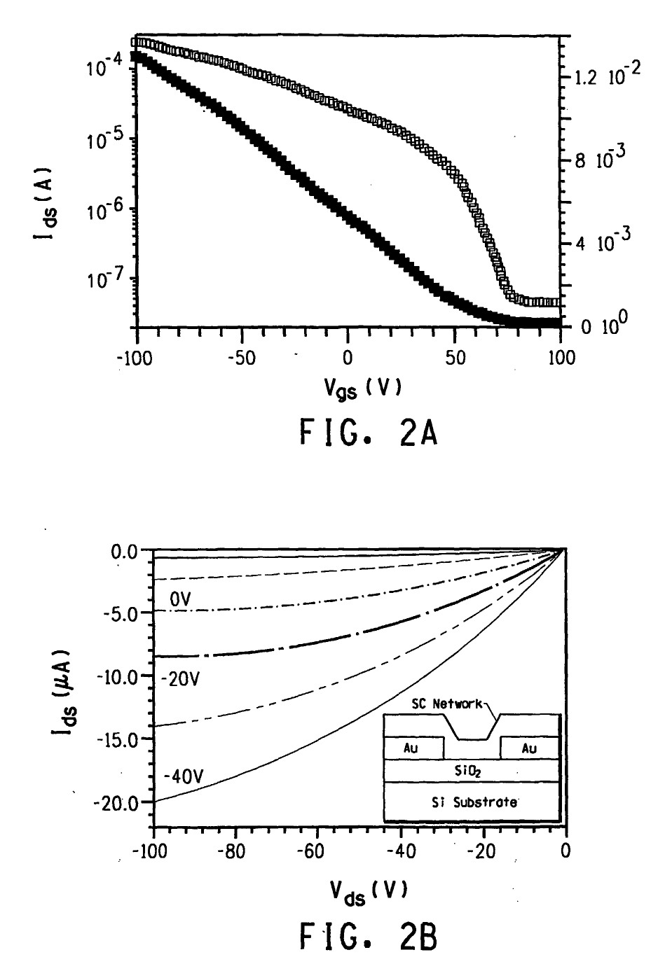

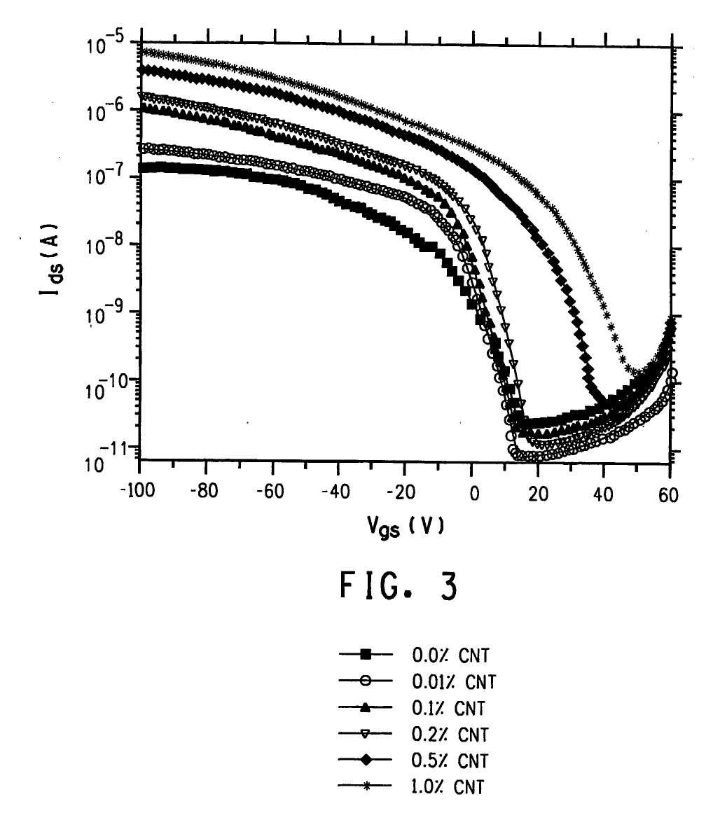

The thiophene solutions with carbon nanotubes are illustrated in Examples 2 and 3. A dispersion of single wall carbon nanotubes in ortho di-chloro benzene (ODCB) at 0.15 mg/ml concentration was tip sonicated for 5 minutes. The solution was then placed in the dry box and mixed into the polythiophene solution to make composites at 0.01, 0.02, 0.05 0.1 and 0.2% by weight CNT's. The I,V characteristics of the transistors. were then measured using a standard Hewlett-Packard 4155 probe station. I,V measurements were performed in a dry box in the dark to avoid the degradation known to be caused on PTP by oxygen and light. FIG. 1A shows a cross section of the test transistor configuration. FIG. 1B shows the I,V curve of Example 1. FIG. 2A shows the gate sweep of the transistor of Example 2. FIG. 2B shows the I,V curve of the transistor of Example 2. FIG. 3 shows the I,V curve of the transistor of Example 3. The I,V characteristics and gate sweeps of composites at 0.02% SWNT loading are shown in FIGS. 2A and B. The apparent effective field mobility, derived from the linear and saturation regimes, was μₐₚₚ≅0.13 cm²/Vs. The calculated transconductance was gₘ≅8×10⁻⁵ S/cm. FIG. 3 shows the I,V curves for polythiophene composites at various SWNT concentrations and control polythiophene films.

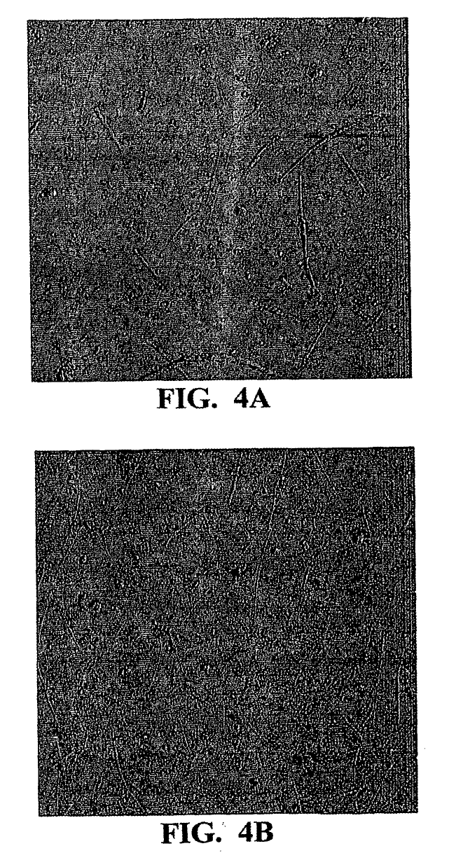

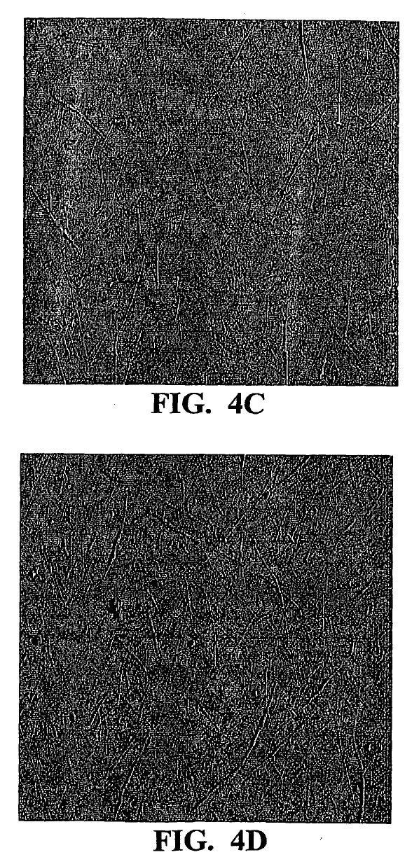

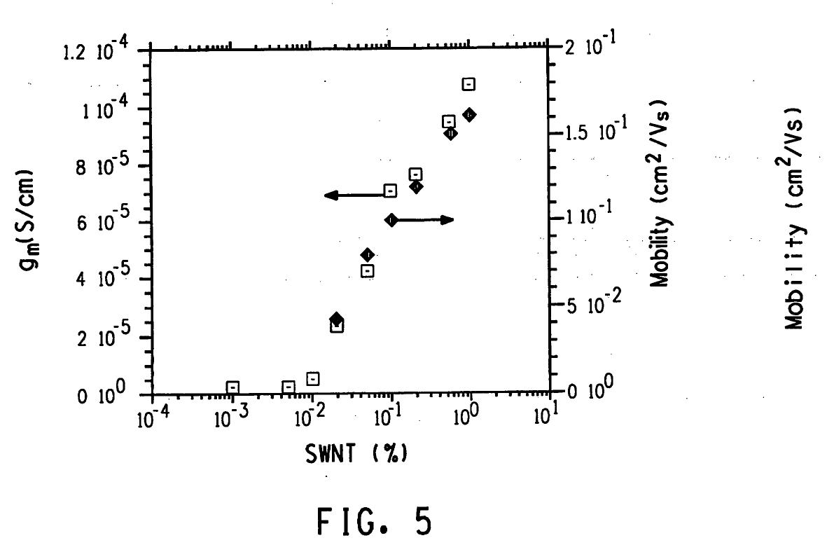

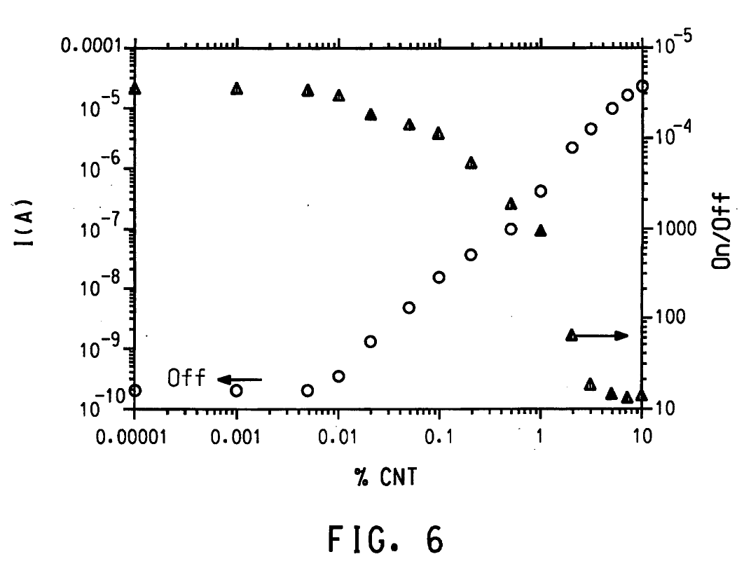

FIGS. 4 A, B, C, and D show atomic force micrographs (AFM) of Example 3 with 0.05, 0.1, 0.25 and 1% carbon nanotube content. The mobilities and transconductances, calculated from the linear regime for TFTs with CNT concentrations ranging from 0.0001 to 10%, are shown in FIG. 5. The on/off ratio and the off current was extracted from a gate sweep for the devices of FIG. 5. They are shown in FIG. 6. The measurable off current for low CNT content reflects the presence of metallic links in the semiconducting network. Metallic links effectively reduce the channel length, on and by themselves effectively increasing the mobility.

### EXAMPLE 4

This example demonstrates an alternative path for achieving high transconductance organic transistors by assembling bi-layers of pentacene onto random arrays of single-walled carbon nanotubes (SWNT). As in Example 3, for non-percolating SWNT arrays, the majority of current paths between source and drain follow the highly conducting nanotubes with short, switchable pentacene links completing the circuit. We show here that by varying the connectivity of the underlying nanotube network, the channel length of a thin film transistor can be reduced by nearly two orders of magnitude. Thus, enabling the increase in device transconductance without reduction in the on/off ratio.

Hipco SWNT's ropes, fabricated by CNI, Houston, Tex., were separated into individual tubes with the aid of surfactants. The resulting aqueous dispersion containing metallic and semiconducting tubes was filtered and the surfactant fully removed. The tubes (and small diameter ropes) were dried and re-dispersed in ortho-dichloro benzene (ODCB) at 5 mg/L, 10 mg/L, 20 mg/L, 35 mg/L and 50 mg/L concentrations. The various dispersions were spun at 1000 RPM onto a clean Si wafer with a 2500 Å thermal oxide and pre-patterned Au source/drain electrodes of various channel widths (W) and lengths (L). A 200 Å pentacene overlay evaporated at a base pressure of ˜7×10⁻⁸ torr. and at 0.2 Å/s, completed the device. Electrical performance was characterized using an Agilent 4155° C.

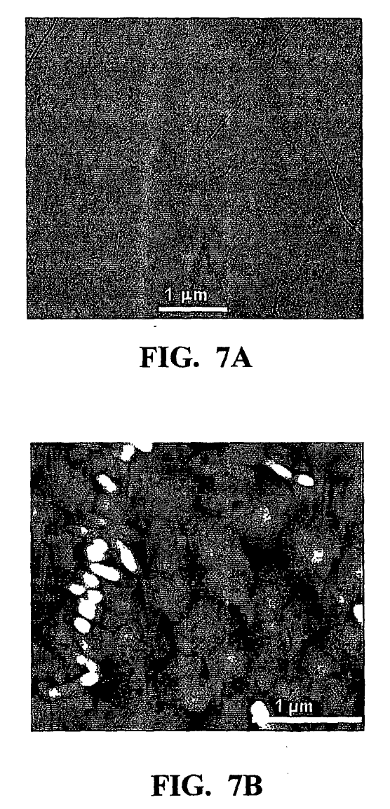

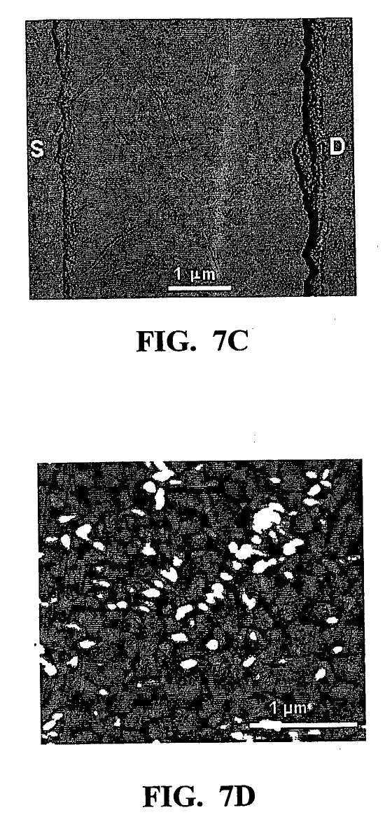

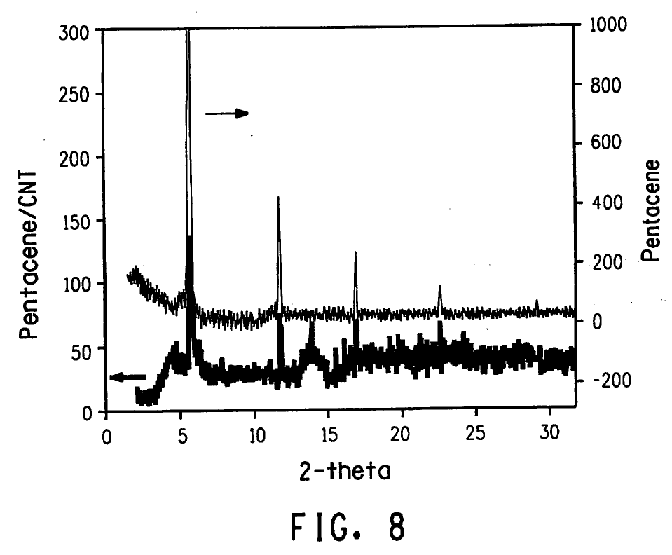

AFM images of SWNT arrays spun onto Si/SiO₂ wafers from 5 and 20 mg/L SWNT dispersions and the corresponding SWNT/pentacene bi-layers are shown in FIG. 7 a-d. The x-ray spectra of pentacene and pentacene on a carbon nanotube array spun at 20 mg/L are shown in FIG. 8

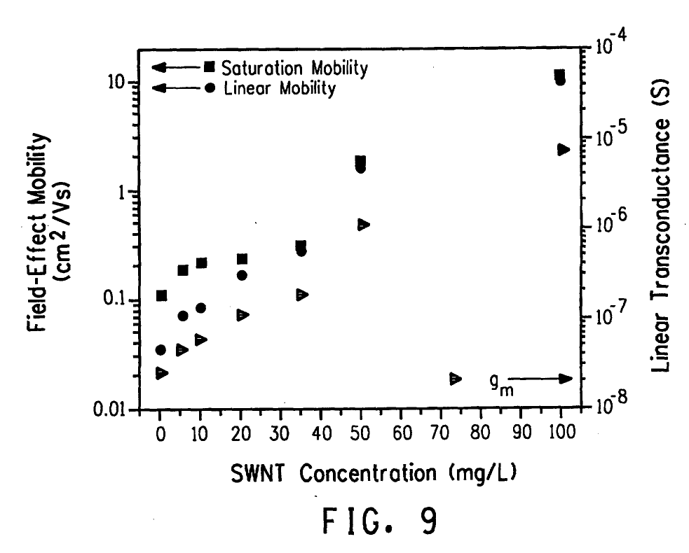

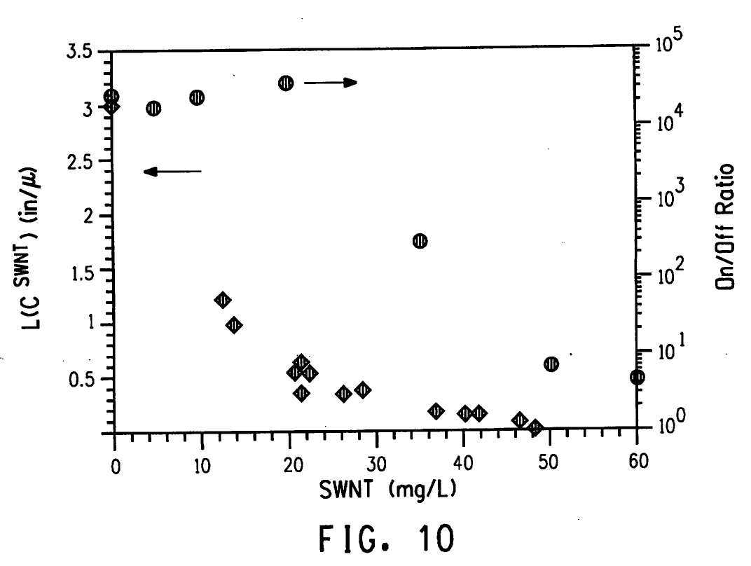

The effective field effect mobilities and transconductance of pentacene-SWNT TFT's bi-layers as a function of SWNT concentrations are shown in FIG. 9. Both parameters increase by about 5×from 0.036 cm²/Vs to 0.17 cm²/VS and 2.48 10⁻⁸ to 1.17 10⁻⁷ S as the underlying SWNT network approaches percolation. Mobilities are calculated from TFT transfer characteristics at V_{ds}=−50 V in the saturation-region (circles) and at V_{ds}=−5 V in the linear-region (squares). Linear transconductance corresponds to V_{ds}=−5 V, labeled by triangles.

FIG. 10 shows the channel length L(c) for random arrays for tubes and on/off ratio for bi-layer devices as a function of SWNT content. The channel length of the random array of tubes decreases exponentially with increasing SWNT concentration reaching percolation at 50 mg/L, the onset of the rapid reduction in on/off ratio. Although the effective mobility and transconductance reach 10 cm²/Vs at high carbon nanotube concentration, a concurrent increase in OFF current leads to ON/OFF ratios of less than 10 as the SWNT concentration approaches 100 mg/L.

In TFT devices comprising non-percolating nanotube networks, the presence of conducting SWNT rods merely reduces the distance between source and drain. In contrast, conducting pathways above percolation lead to a rapid increase in off current, thus lowering of the on/off ratio. In this example the semiconducting overlay is pentacene.

As in the single layer composite work, the majority of the current paths between source and drain follow the highly conducting nanotubes with short, switchable pentacene links completing the circuit. In principle, one would expect the increase in transconductance to scale inversely with channel length reduction. Thus, nearly 2 orders of magnitude increase in transconductance reflecting a 100×reduction in channel length. FIG. 10 shows that the channel length of the SWNT underlay indeed decreases by 2 orders of magnitude as the network approaches percolation. However, the transconductance of the pentacene bi-layer increases merely by a factor of 5×reflecting a concurrent decrease in the crystallinity of the pentacene overlay. Since transconductance is proportional to mobility and inversely proportional to channel length, the results in FIG. 2 suggest that the 100×decrease in channel length is accompanied by a 20×decrease in the mobility of the pentacene overlay. The decrease in mobility is associated to a decrease in the crystallinity of the pentacene overlay (FIG. 8).

The effective channel length in FIG. 10 was estimated from AFM images of non-percolating nanotube arrays spun at 1000 PRM onto the pre-patterned wafers from 5, 10, 20, 35 and 50 mg/L SWNT dispersions. The channel lengths were obtained by adding the various breaks along each possible path. The total number of tubes/μ² measured for each image. The channel length L for each concentration, c, was the average of the many paths lengths obtained for several images at each of the concentrations.

### EXAMPLE 5

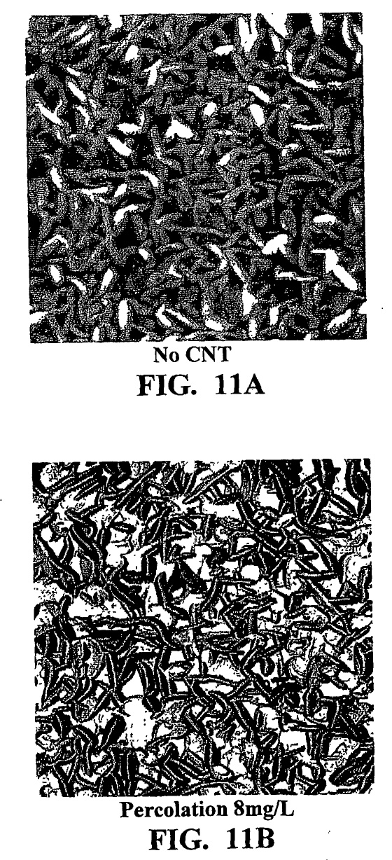

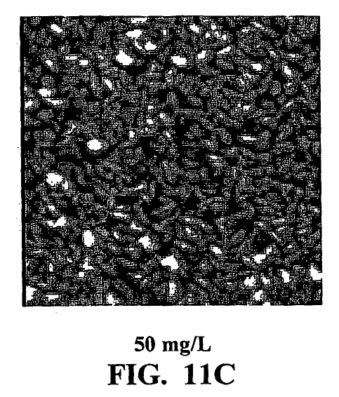

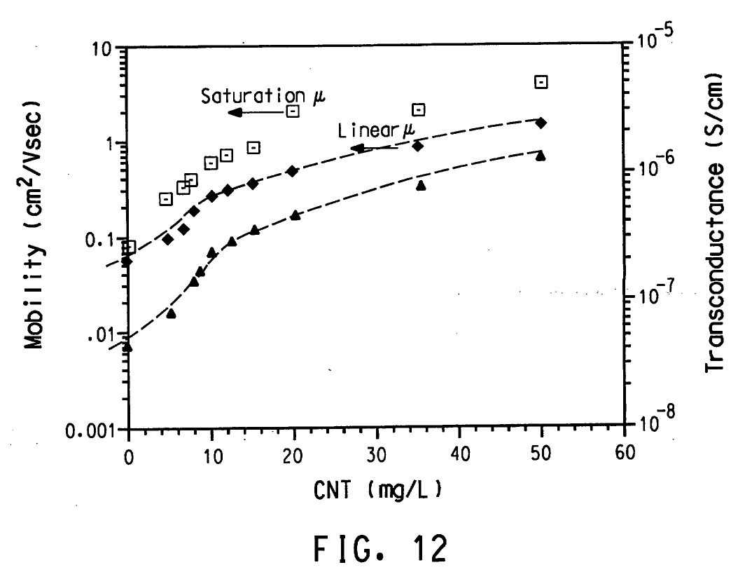

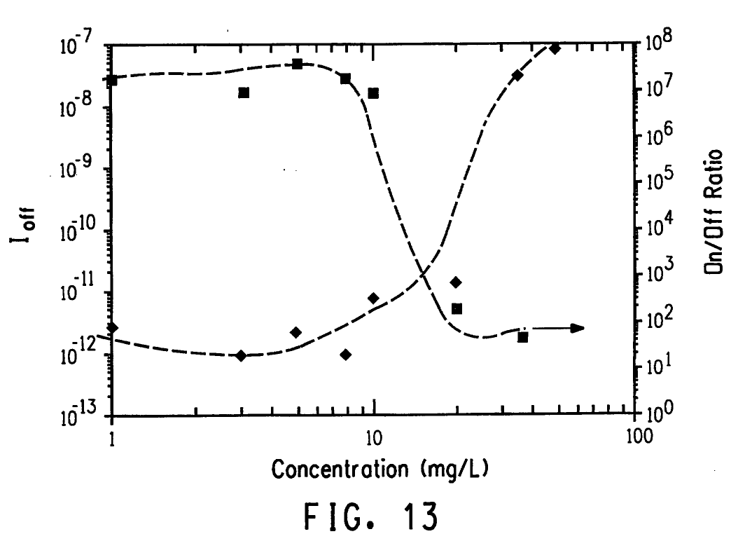

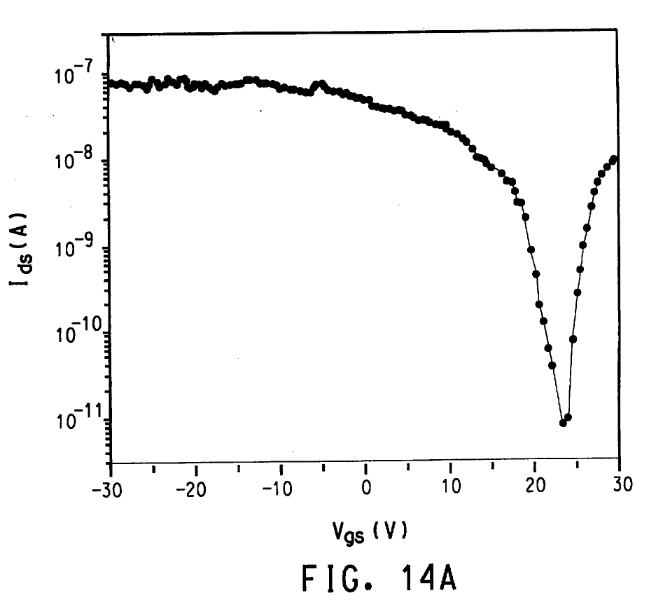

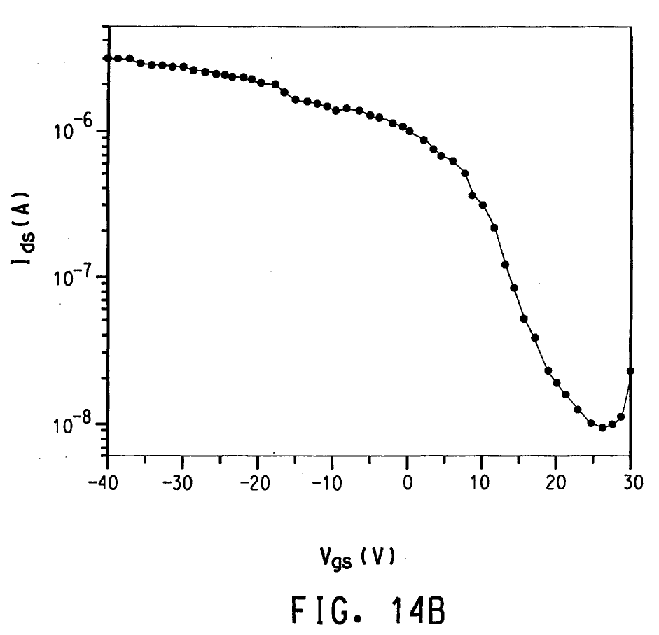

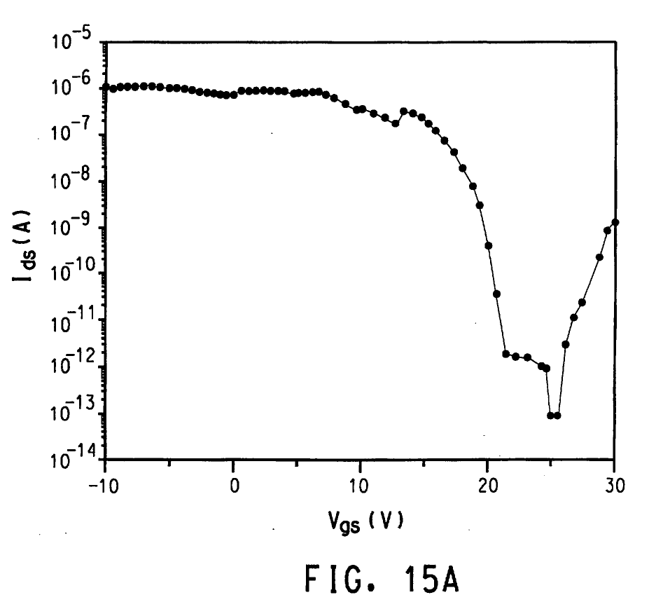

A short channel length transistor was created through the exploitation of non-percolating SWNT arrays that are connected via semiconducting links that have a similar morphology to the underlying nanotube network. This method can raise the transconductance of our device by nearly two orders of magnitude to 1 cm²/V sec, mobility of a-Si. The factor of 40 observed here for the amorphous bi-layers reflects a significant improvement relative to Example 4 in which the pentacene crystallinity was reduced by the presence of their underlying nanotube network. The example illustrates that the potential of the bi-layers can be achieved with more amorphous semiconductor that grow conforming to the underlying network of tubes. Since the origin of this mobility improvement relies on the reduction of the effective source drain distance via the formation of a non-percolating arrays of SWNT's, on/off ratio of 10⁵ can be maintained. The material alkyl antracene is described in U.S. provisional patent application 672177 by Hong Meng. The AFM of a 400 Å semiconducting films evaporated onto a Si wafer with a SiO₂ layer is shown in FIG. 11. FIG. 11a contains no CNT's. The substrate was maintained at 60° C. during deposition and the deposition rate was 1 A/sec. The AFM's of films of equal thickness evaporated at similar conditions onto a semiconducting arrays spun from a 8 mg/L (FIG. 11b) and 50 mg/L (FIG. 11c) solution are shown in the middle and right hand side. The mobility and transconductance of these bi-layers as a function of nanotube concentration are shown in FIG. 12. The effective mobility of these bi-layers is higher than that of amorphous-Si. The off current and on/off ratio are shown in FIG. 13. As in the previous examples, these devices have an operational window, near percolation, in which the on/off ratio is maintained at 10⁵ while the mobility has increased by 40×.

### EXAMPLES 6-10

These examples illustrate a semiconducting carbon nanotube network in a polyaniline (PANI) matrix. The polyaniline was slightly doped to a conductivity of 10⁻⁵ohm-cm. The single wall carbon nanotubes (SWNT) were well dispersed in water to a concentration of 0.015 mg/ml with 1% surfactant (SDS) provided by Strano. The SWNT resulting from this dispersion were mostly single tubes. The dispersion was used in the composites without further sonication. A 3% by weight solution of polyaniline in distilled water as prepared at room temperature. The polyaniline solution was then mixed with the SWNT in water as previously described to SWNT concentrations of 0, 1%, 2%, 5% and 10%. Zonyl FSN (by DuPont, Wilmington, Del.) to 6 to 10% by weight concentration was added as a coating aid. The amounts of the composites used in Examples 6-10 are indicated below:

Example 6, control 250 mg PANI, no nanotubes
Example 7, 1% CNT in PANI: 5 ml SWNT solution, 250 mg PANI
Example 8, 2% CNT in PANI: 5 ml SWNT solution, 120 mg PANI
Example 9, 5% CNT in PANI: 5 ml SWNT solution, 68 mg PANI
Example 10, 10% CNT in PANI: 10 ml SWNT solution, 68 mg PANI

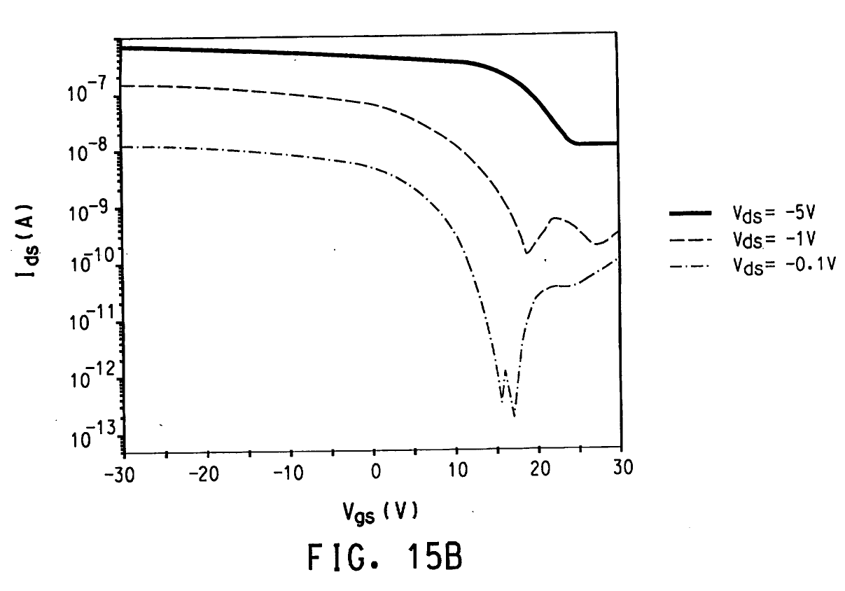

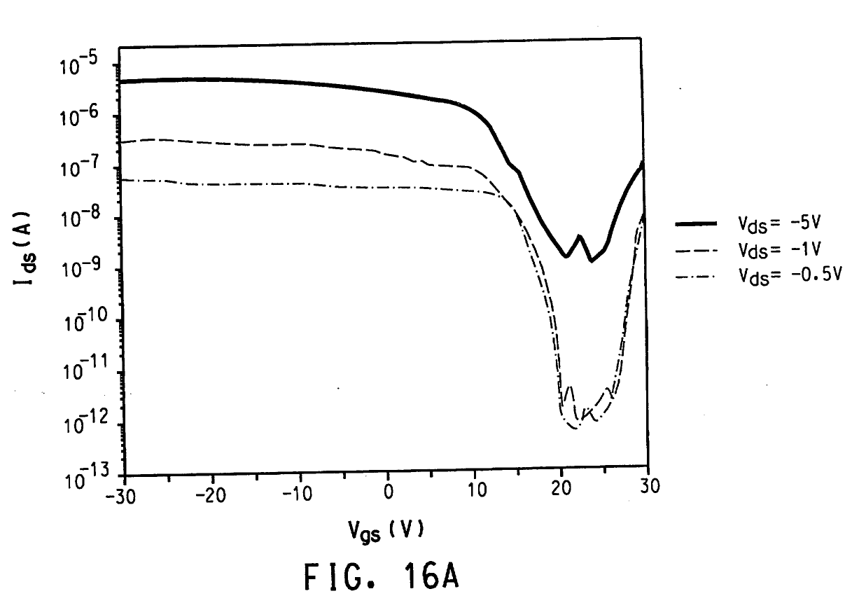

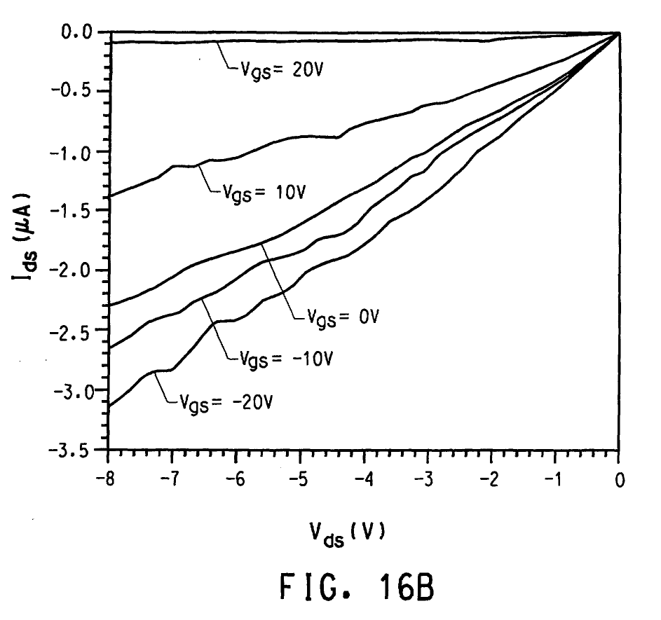

The solutions were spun onto the SiO₂/Si wafers described in Examples 1-3 at 2000 rpm and baked in an oven at 60° C. for 5 minutes. The TFT characteristics were measured as previously described. The Igate sweepcurves are shown in FIG. 14A for 1% CNT in PANI and in FIG. 14B for 2% CNT in PANI. FIG. 15A shows the gate sweeps and I,V curves of Example 9 and FIG. 15B shows the gate sweep for Example 10.

### EXAMPLES 11-13

These examples illustrate the formation of a semiconducting carbon nanotube network in an insulating matrix. The host matrix is an insulating terpolymer of methyl methacrylate/butyl methacrylate/methacrylic acid/glycydil methacrylate in a ratio of 70/25/3/2. This has a glass transition (Tg) of 70° C. The latex was 33% by weight in water. The single wall carbon nanotubes were well dispersed in water to a concentration of 0.015 mg/ml with 1% surfactant (SDS) which were provided by Michael Strano from University of Illinois. The SWNT resulting from this dispersion were mostly single tubes and were used in the composites without further sonication. The SWNT dispersion was then mixed with the latex. Zonyl FSN was added to 1 part in 10⁶ by weight of total solution to aid with coating. In Example 11 (control sample), the latex was spun onto the patterned clean wafers previously described. I,V curves are shown in FIG. 9. In Examples 12 and 13, 1% and 0.5% SWNT are dispersed in the latex. The compositions are listed below:

### Example 12 1% SWNT in LATEX: 10 ml CNT, 45 mg LATEX

### Example 13 0.5% SWNT in LATEX: 6.6 ml CNT, 60 mg LATEX

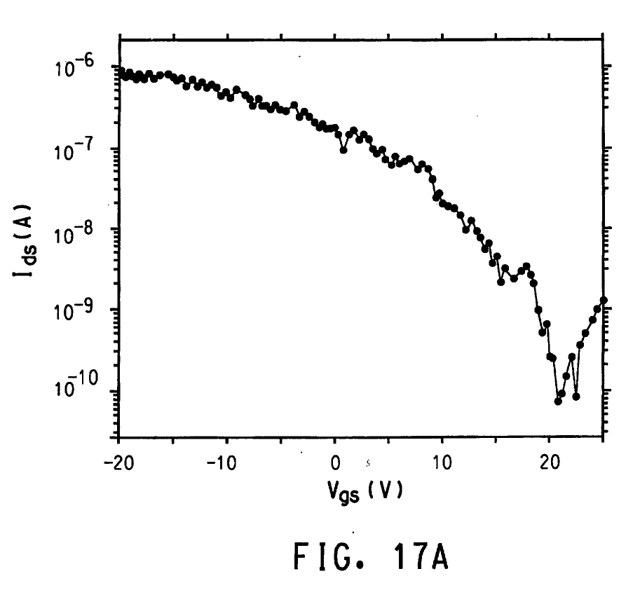

The formulations were then spun onto the clean pattern Si wafers previously described at 2000 rpm. The spun samples were then baked in an oven at 60° C. for 5 minutes. The I,V curves were measured and mobility calculated from the linear regime. FIG. 16A shows the gate sweep of Examples 13. FIG. 16B shows the I,V curve of Example 13.

### EXAMPLE 14

These examples illustrate the formation of a semiconducting carbon nanotube network coated with a conducting polyaniline (1:4 ratio) in an insulating matrix. As in Example 4, the polyaniline is soluble in water to a concentration of 3% by weight. As in Example 9, the host matrix is an insulating terpolymer of methyl methacrylate/butyl methacrylate/methacrylic acid/glycydil methacrylate. This has a glass transition (Tg) of 70° C. The latex was 33% by weight in water. The single wall carbon nanotubes were well dispersed in water to a concentration of 0.015 mg/ml with 1% surfactant (SDS) were provided by Strano. The SWNT resulting from this dispersion were mostly single tubes and were used in the composites without further sonication. Zonyl FSN was added to 1 part in 10⁶ by weight of total solution to aid with coating. The SWNT dispersion was mixed with the PANI solution in a ratio of 1:4. That is 18 ml containing approximately 0.27 mg of SWNTs was mixed with 38 ml of 3% PANI solution containing 1.14 mg of PANI. This was finally mixed with 228 ml of 33% latex solution containing about 76 mg of latex.

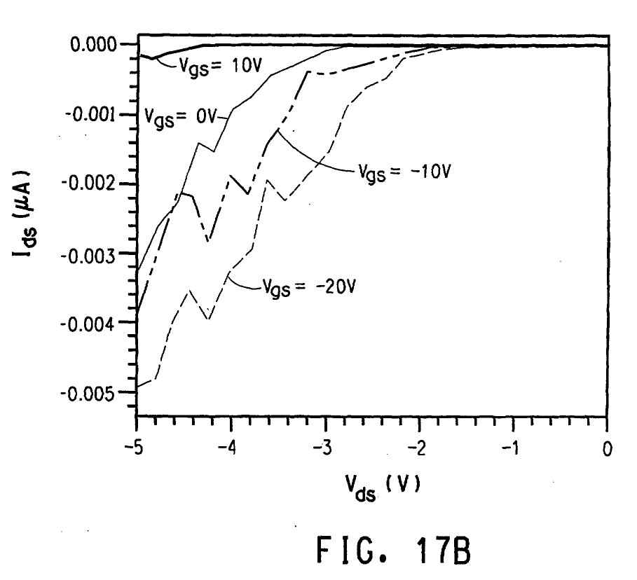

The formulation was then spun onto the clean patterned Si wafers previously described at 2000 rpm. The spun samples were then baked in an oven at 60° C. for 5 min. The I,V curves were measured and mobility calculated from the linear regime. FIG. 17A shows the gate sweep and FIG. 17B shows the I,V curves of Examples 17.

1-18. (canceled)

19. A transistor comprising:
a) a first layer comprising carbon nanotubes wherein the nonotubes are dispersed from ropes from which they are formed;
b) a second layer comprising a semiconductor wherein the second layer is in contact with the first layer.

20. A process comprising:
a) depositing a first layer comprising carbon nanotubes wherein the nanotubes are dispersed from ropes in which they are formed on a substrate;
b) depositing a semiconductor on the first layer.

21. The transistor of claim 19 wherein the semiconductor is pentacene.

22. The process of claim 20 wherein the semiconductor is pentacene.
